(19) United States
(12) Patent Application Publication
(10) Pub. No.: US 2025/0393442 A1
(43) Pub. Date: Dec. 25, 2025

(54) DISPLAY DEVICE, ELECTRONIC DEVICE INCLUDING THE SAME, AND MANUFACTURING METHOD THEREOF

(71) Applicant: Samsung Display Co., Ltd., Yongin-si (KR)

(72) Inventors: BYEONGKYU PARK, Yongin-si (KR); HYOCHANG KIM, Yongin-si (KR); Young Eun OH, Yongin-si (KR)

(21) Appl. No.: 19/085,543

(22) Filed: Mar. 20, 2025

(30) Foreign Application Priority Data
Jun. 25, 2024 (KR) 10-2024-0083188
Jul. 4, 2024 (KR) 10-2024-0088219

(51) Int. Cl. H10K 59/80; H10K 59/12; H10K 102/00

(52) U.S. Cl. CPC H10K 59/873; H10K 59/1201; H10K 2102/311

(57) ABSTRACT

A display device according to one or more embodiments includes a substrate, a display layer disposed on the substrate, a protective layer disposed on a rear surface of the substrate, and an adhesive layer disposed between the display panel and the protective layer, in which the substrate includes a first area where the display layer is disposed, a bending area extending and bent from the first area, and a second area connected to the bending area and overlapping the first area, the protective layer includes an opening overlapping the bending area, and the protective layer is made of a polyimide material.

### CROSS-REFERENCE TO RELATED APPLICATION

The present application claims priority to and the benefit of Korean Patent Application No. 10-2024-0088219, filed on Jul. 4, 2024, and Korean Patent Application No. 10-2024-0083188, filed on Jun. 25, 2024, in the Korean Intellectual Property Office, the entire disclosure of each of which is incorporated herein by reference.

### BACKGROUND

### 1. Field

The present disclosure relates to a display device, an electronic device including the display device, and a manufacturing method of the display device.

### 2. Description of the Related Art

A display device includes pixels that may display an image on a display screen by adjusting or controlling brightness of each pixel. In addition, the display device may include a touch sensing unit to detect (capable of detecting) user instructions (e.g., a user's touch). The display device may include a display panel on which pixels are arranged. The touch sensing unit may be provided on the display panel. For example, the display panel may include the touch sensing unit, or the panel including the touch sensing unit may be attached to the display panel. In other words, this touch sensing unit may either be integrated into the display panel or attached as a separate layer on top of the display panel.

### SUMMARY

Aspects according to one or more embodiments of the present disclosure are directed toward a display device with (having) enhanced (e.g., excellent or suitable) folding characteristics and high-temperature stability, an electronic device including the display device, and a manufacturing method of the display device. Additional aspects will be set forth in part in the description which follows and, in part, will be apparent from the description, or may be learned by practice of the presented embodiments of the disclosure.

According to one or more embodiments, a display device includes a substrate, a display layer on a first surface of the substrate, a protective layer on a second surface of the substrate, the second surface facing away from the first surface, and an adhesive layer between the display layer and the protective layer, in which the substrate includes a first area where the display layer is arranged, a bending area extending and bent from the first area, and a second area connected to the bending area and overlapping the first area, the protective layer includes an opening overlapping the bending area, and the protective layer is made of a polyimide material.

The protective layer may be colored or transparent.

The protective layer may have a UV light transmittance of less than 10%.

The display device may be folded based on a folding axis crossing the display layer.

The display device may further include a buffer member on a surface of the protective layer.

The substrate may include a display area and a non-display area, and the bending area and the second area may overlap the non-display area.

The adhesive layer may include an acrylic compound.

An adhesion of the adhesive layer may be about 300 gf/inch to about 1000 gf/inch.

The adhesive layer may include a UV initiator.

A side surface of the protective layer may have a concave-convex shape.

According to one or more embodiments, a method of manufacturing a display device includes providing an adhesive layer on a polyimide film, arranging a mask on the adhesive layer and irradiating UV light, attaching the adhesive layer irradiated with UV light to a surface of a display panel, and removing a portion of the polyimide film and a portion of the adhesive layer.

In the irradiating of the UV light, an adhesion of the adhesive layer may be improved.

By irradiating of UV the light, the adhesive layer may include a first adhesive area having a first adhesion and a second adhesive area having a second adhesion, and the first adhesion may be greater than the second adhesion.

The method may further include performing a laser cutting process along an edge of the second adhesive area.

The removing of the portion of the polyimide film and the portion of the adhesive layer may include removing the second adhesive area of the adhesive layer and a portion of the polyimide film corresponding to the second adhesive area.

The polyimide film may have a UV light transmittance of less than about 10%.

The polyimide film may be colored or transparent.

The display device may be folded based on a folding axis crossing the display panel.

The adhesive layer may include a UV initiator.

The adhesive layer may include an acrylic compound.

According to one or more embodiments, an electronic device includes the display device. The electronic device may be selected from among a television, a laptop, a monitor, a billboard, the Internet of Things (IoT), portable electronic devices, a mobile phone, a smart phone, a tablet personal computer (PC), a mobile communication terminal, an electronic notebook, an electronic book, a portable multimedia player (PMP), a navigation, an ultra mobile PC (UMPC), wearable devices, a smart watch, a watch phone, a glasses-type (kind) display, a head mounted display (HMD), a center information display (CID) on a car's instrument panel and/or a car's center fascia and/or dashboard, a room mirror display that replaces a car's side mirror, and a display on a rear surface of a front seat as entertainment for a car's rear seat.

According to one or more embodiments, it is possible to provide a display device with (having) enhanced (e.g., excellent or suitable) folding characteristics and high-temperature stability and a manufacturing method of the display device.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure.

In the drawings:

FIG. 1 is a perspective view of a display device according to one or more embodiments.

FIG. 2 is a perspective view of a display device according to one or more embodiments.

FIG. 3 is an exploded perspective view of a display device according to one or more embodiments.

FIG. 4 is a cross-sectional view of a portion of a display device according to one or more embodiments.

FIG. 5 is a plan view of a protective layer according to one or more embodiments.

FIGS. 6-13 are diagrams illustrating a manufacturing method of a display device according to one or more embodiments.

FIG. 14 is a graph illustrating UV transmittance for Examples and Comparative Example.

### DETAILED DESCRIPTION

Hereinafter, embodiments of the present disclosure will be described in more detail with reference to the accompanying drawings so that those skilled in the art to which the present disclosure pertains may easily practice the present disclosure. However, the present disclosure may be implemented in one or more suitable different forms and is not limited to embodiments provided herein.

Portions unrelated to the description will not be provided in order to obviously describe the present disclosure, and similar components will be denoted by the same reference numerals throughout the present specification.

In addition, the size and thickness of each component illustrated in the drawings are arbitrarily indicated for convenience of description, and the present disclosure is not necessarily limited to the illustrated size and thickness. In the drawings, the thickness of layers, films, panels, regions, and/or the like, may be exaggerated for clarity. In addition, in the accompanying drawings, thicknesses of some of layers and regions have been exaggerated for convenience of explanation.

In addition, it will be understood that if (e.g., when) an element such as a layer, film, region, or substrate is referred to as being “on” another element, it can be directly on the other element or intervening elements may also be present. In contrast, if (e.g., when) an element is referred to as being “directly on” another element, there are no intervening elements present. In addition, if (e.g., when) an element is referred to as being “on” a reference element, it can be arranged on or beneath the reference element, and is not necessarily arranged on the reference element in an opposite direction to gravity.

In addition, unless explicitly described to the contrary, the terms “comprise(s)/comprising,” “include(s)/including,” “have/has/having” or similar terms, will be understood to imply the inclusion of stated elements but not the exclusion of any other elements. Additionally, these terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Further, throughout the specification, the word “plane” refers to a view if (e.g., when) a target is viewed from the top, and the word “cross section” refers to a view if (e.g., when) a cross section of a target taken along a vertical direction is viewed from the side.

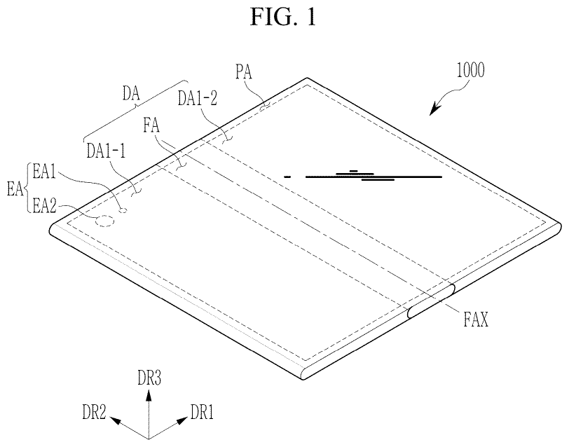

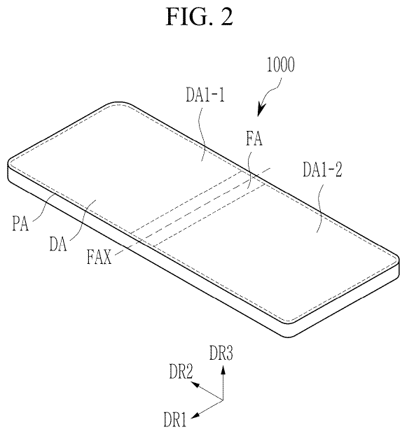

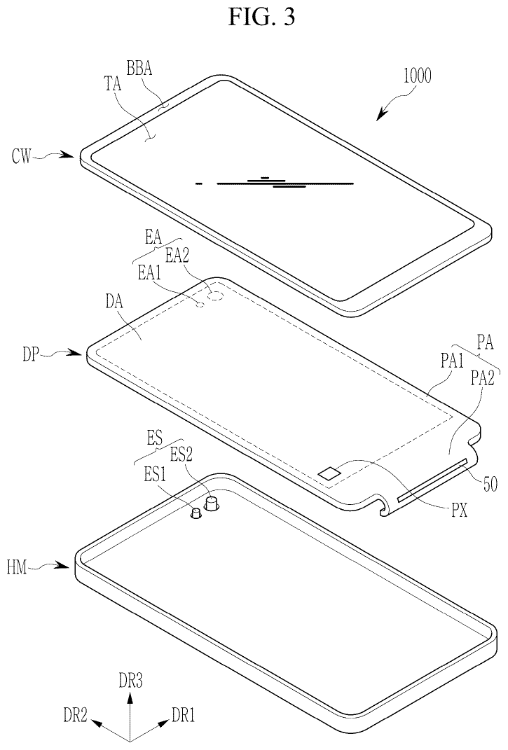

Hereinafter, a display device according to one or more embodiments will be described with reference to FIGS. 1 to 3. FIG. 1 is a perspective view of a display device according to one or more embodiments. FIG. 2 is a perspective view of the display device according to one or more embodiments. FIG. 3 is an exploded perspective view of the display device according to one or more embodiments.

First, referring to FIG. 1, a display device 1000 according to one or more embodiments is a device that displays a moving image or a still image, and may be used as a display screen for one or more suitable products (e.g., electronic devices) of a television, a laptop, a monitor, a billboard, the Internet of Things (IoT), and/or the like, as well as portable electronic devices such as a mobile phone, a smart phone, a tablet personal computer (PC), a mobile communication terminal, an electronic notebook, an electronic book, a portable multimedia player (PMP), a navigation, and/or an ultra mobile PC (UMPC). In addition, the display device 1000 according to one or more embodiments may be used in wearable devices (e.g., wearable electronic devices) such as a smart watch, a watch phone, a glasses-type (kind) display, and/or a head mounted display (HMD). In addition, the display device 1000 according to one or more embodiments may be used as a center information display (CID) that is arranged on a car's instrument panel and/or a car's center fascia and/or dashboard, a room mirror display that replaces a car's side mirror, and a display that is arranged on a rear surface of a front seat as entertainment for a car's rear seat. For convenience of description, FIG. 1 illustrates the display device 1000 being used as a smart phone.

The display device 1000 may display an image toward a third direction DR3 on a display surface parallel to a first direction DR1 and a second direction DR2, respectively. The display surface on which the image is displayed may correspond to a front surface of the display device 1000. The image may include a still image as well as a moving image.

In the present embodiments, the front surface (or upper surface) and the rear surface (or lower surface) of each member are defined based on the direction in which the image is displayed. The front and the rear surfaces are opposite each other in the third direction DR3, and a normal direction of each of the front and rear surfaces may be parallel to the third direction DR3. A separation distance between the front and rear surfaces in the third direction DR3 may correspond to a thickness of the display panel in the third direction DR3.

In one or more embodiments, the display device 1000 may be a foldable device. In the present specification, the term “foldable device” is used to refer to a device that can be folded, including not only a device in a folded state, but also a device that may have both a folded state and an unfolded state. That is, the term “foldable device” as used herein includes both a device that is in a folded state and a device that is in an unfolded state and is capable of being in the folded state. In addition, the folding typically includes folding at an angle of about 180°, but the present disclosure is not limited thereto, and the case where the folding angle exceeds or falls short of (e.g., is less than) 180°, for example, where the folding is made at an angle of 90° or more and less than 180°, or 120° or more and less than 180° may also be understood as folded. In addition, the term “folded state” may refer to a bent state (e.g., partially folded state) from the unfolded state, even if the complete folding does not occur. For example, even if the display device is bent at an angle of 90° or less, as long as a maximum folding angle is 90° or more, it may be expressed that the display device is in the folded state in order to be distinguished from the unfolded state. That is, if the display device is capable of having a maximum folding angle of 90° or more, a state in which it is bent at an angle less than the maximum folding angle, such as less than 90°, is still referred to as a folded state to distinguish from the unfolded states. A radius of curvature if (e.g., when) folded may be 5 mm or less, for example, may be in the range of 1 mm to 2 mm, or about 1.5 mm, but the present disclosure is not limited thereto.

In one or more embodiments, the display device 1000 may include a display area DA, a component area EA, and a non-display area PA.

In the display area (DA) (hereinafter, also referred to as a main display area) and the component area EA, a plurality of light-emitting diodes and a plurality of pixel circuit units for generating and transmitting light-emitting current to each of the plurality of light-emitting diodes are formed. Here, one light-emitting diode and one pixel circuit unit are referred to as a pixel. In the display area DA and the component area EA, one pixel circuit unit and one light-emitting diode may be formed one-to-one.

The display area DA may include a 1-1th display area DA1-1, a 1-2th display area DA1-2, and a folding area FA. The 1-1th display area DA1-1 and the 1-2th display area DA1-2 may be arranged on two opposing sides, for example, the left and right sides, respectively, based on (or centered on) a folding axis FAX, and the folding area FA may be arranged between the 1-1th display area DA1-1 and the 1-2th display area DA1-2. In this case, if (e.g., when) folded outward based on (e.g., along) the folding axis FAX, the 1-1th display area DA1-1 and the 1-2th display area DA1-2 may be arranged on both sides (e.g., opposite sides) in the third direction DR3, and images may be displayed (e.g., simultaneously) in both directions. In addition, if (e.g., when) folded inward based on (e.g., along) the folding axis FAX, the 1-1th display area DA1-1 and the 1-2th display area DA1-2 may not be visible from the outside.

According to one or more embodiments, the folding axis FAX may extend along the second direction DR2 and may cross (e.g., extend from one edge to an opposing edge of) the display area DA. In FIG. 1, one folding area FA is illustrated, but the display device 1000 according to one or more embodiments may include one or more folding areas FAs. The one or more folding areas FAs may be folded around different axes, for example, an axis parallel to the first direction DR1 and/or an axis parallel to the second direction DR2, and the position and width of the folding area FA in the display device 1000 may be variously suitably changed. The non-display area PA is adjacent to the display area DA and may be around (e.g., surround) the display area DA. No image is displayed in the non-display area PA, and a driving circuit, a driving wiring, and/or the like, for driving the display area DA may be arranged.

The component area EA may include a first component area EA1 and a second component area EA2. The first component area EA1 and the second component area EA2 may be at least partially surrounded by the display area DA. The first component area EA1 and the second component area EA2 are illustrated as being spaced and/or apart (e.g., spaced apart or separated) from each other, but the present disclosure is not limited thereto and the first component area EA1 and the second component area EA2 may be at least partially connected. The first component area EA1 and the second component area EA2 may be areas where optical elements (see ES of FIG. 3; hereinafter, also referred to as components) that use infrared rays, visible light, sound, and/or the like, are arranged therebelow.

Referring to FIG. 2, the display device 1000 according to one or more embodiments may have a length of one side along the second direction DR2 longer than a length of one side along the first direction DR1. When viewed by a user, it may have a rectangular shape that is long in a vertical direction. That is, the display device 1000 according to one or more embodiments may have a rectangular shape with one side (e.g., along the second direction DR2) being longer in length than another side (e.g., along the first direction DR1).

The display device 1000 according to one or more embodiments may include the folding axis FAX extending in the first direction DR1. The display device 1000 may be folded based on (e.g., along) the folding axis FAX, and the folded display device 1000 may have a length reduced by half in the second direction DR2.

Referring to FIG. 3, an example structure of the display device 1000 will be described. The display device 1000 of FIG. 3 is illustrated as a flat type (kind), but may also be applied to a foldable display device, as in the embodiments of FIGS. 1 and 2.

The display device 1000 may include a cover window CW, a housing HM, a display panel DP, and an optical element ES. In one or more embodiments, the cover window CW and the housing HM may be coupled to form an exterior of the display device 1000.

The cover window CW may include an insulating panel. For example, the cover window CW may be made of glass, plastic, and/or a (e.g., any suitable) combination thereof.

A front surface of the cover window CW may define the front surface of the display device 1000. The transmissive area TA may be an optically transparent area. For example, the transmissive area TA may be an area having a visible light transmittance of about 90% or more.

A blocking area BBA may define a shape of the transmissive area TA. The blocking area BBA may be adjacent to the transmissive area TA and may be around (e.g., surround) the transmissive area TA. The blocking area BBA may be an area having a relatively low light transmittance compared to the transmissive area TA. The blocking area BBA may include an opaque material that blocks light. The blocking area BBA may have a set or predetermined color. The blocking area BBA may be defined by a bezel layer provided separately from a transparent substrate defining the transmissive area TA, or by an ink layer formed by being inserted into or colored on the transparent substrate.

The display panel DP may include display pixels PX that display an image and a driving unit 50, and the display pixels PX are arranged within the display area DA and the component area EA. The display panel DP may include a front surface including a display area DA and a non-display area PA. In one or more embodiments, the display area DA and the component area EA, including the pixel, may be areas where an image is displayed, and at the same time, areas where a touch sensor is arranged on the upper side in the third direction DR3 of the pixel to detect an external input.

The transparent area TA of the cover window CW may overlap at least partially with the display area DA and the component area EA of the display panel DP. For example, the transparent area TA may overlap with the front surface of the display area DA and the component area EA, or overlap with at least part of the display area DA and the component area EA. Accordingly, a user may view an image through the transparent area TA or provide an external input based on the image. However, the present disclosure is not limited thereto. For example, the area where the image is displayed and the area where the external input is detected may be separated from each other.

The non-display area PA of the display panel DP may overlap at least partially with the blocking area BBA of the cover window CW. The non-display area PA may be an area covered by the blocking area BBA. The non-display area PA may include a first non-display area PA1 where the display area DA is arranged on the outside, and a second non-display area PA2 including a driving unit 50, a connecting wire, and a bending area. In an embodiment illustrated in FIG. 3, the first non-display area PA1 is arranged on three sides of the display area DA, and the second non-display area PA2 is arranged on the remaining side of the display area DA.

In one or more embodiments, a part of the non-display area PA of the display panel DP may be bent. In this case, a part of the non-display area PA may be directed (e.g., bent) toward the rear surface of the display device 1000, so that the surface area of the blocking area BBA shown on the front surface of the display device 1000 may be reduced. In an embodiment illustrated in FIG. 3, the second non-display area PA2 may be bent and arranged on the rear surface of the display area DA and then assembled (e.g., with other parts of the display device 1000).

The first component area EA1 may include a display layer including a transparent part through which light and/or sound may pass and a plurality of pixels. The transparent part is arranged between adjacent pixels and is composed of a layer through which light and/or sound may pass. The transparent part may be arranged between adjacent pixels, and according to one or more embodiments, a layer through which light does not pass, such as a light-shielding member, may overlap the first component area EA1. The number of pixels (hereinafter also referred to as resolution) per unit area of pixels included in the display area DA (hereinafter also referred to as normal pixels) and the number of pixels per unit area of pixels included in the first component area EA1 (hereinafter also referred to as first component pixels) may be the same. That is, the number of pixels per unit area may be referred to as resolution, the pixels in the display area DA may be referred to as normal pixels, and the pixels in the first component area EA1 may be referred to as first component pixels. In one or more embodiments, the display area DA may have the same pixel resolution as the component area EA1.

The second component area EA2 includes an area (hereinafter also referred to as a light-transmitting area) composed of a transparent layer through which light may pass, and the light-transmitting area may have a structure in which it is not formed with a conductive layer or a semiconductor layer, and may not include a layer including a light-shielding material, for example, a pixel definition layer, and/or an opening where the light-shielding material overlaps with a position corresponding to the second component region EA2, to not block light. The number of pixels per unit area of pixels included in the second component area EA2 (hereinafter also referred to as second component pixels) may be smaller than the number of pixels per unit area of normal pixels included in the display area DA. As a result, the resolution of the second component pixels may be lower than that of the normal pixels.

The driving unit 50 may be mounted on the second non-display area PA2, may be mounted on the bending part, or may be arranged on one of the two sides (e.g., opposite sides) of the bending part. The driving unit 50 may be provided in the form of a chip.

The driving unit 50 may be electrically connected to the display area DA and the component area EA to transmit electrical signals to pixels of the display area DA and the component area EA. For example, the driving unit 50 may provide data signals to pixels PX arranged in the display area DA. In one or more embodiments, the driving unit 50 may include a touch driving circuit and may be electrically connected to a touch sensor arranged in the display area DA and/or the component area EA. In one or more embodiments, the driving unit 50 may include one or more suitable circuits in addition to the circuits described above or may be designed to provide one or more suitable electrical signals to the display area DA.

In one or more embodiments, the display device 1000 may have a pad part arranged at an end of the second non-display area PA2 and may be electrically connected to a flexible printed circuit board (FPCB) including a driving chip by the pad part. Here, the driving chip arranged on the flexible printed circuit board may include one or more suitable driving circuits for driving the display device 1000, connectors for power supply, and/or the like. According to some embodiments, a rigid printed circuit board (PCB) may be used instead of the flexible printed circuit board.

The optical element ES may be arranged below the display panel DP. The optical element ES may include a first optical element ES1 overlapping the first component area EA1 and a second optical element ES2 overlapping the second component area EA2.

The first optical element ES1 may be an electronic element that uses light or sound. For example, the first optical element ES1 may be a sensor that receives and uses light, such as an infrared sensor, a sensor that outputs and detects light or sound to measure a distance or recognize fingerprints, a small lamp that outputs light, a speaker that outputs sound, and/or the like. In the case of electronic elements using light, light of one or more suitable wavelength bands such as visible light, infrared light, and ultraviolet light may be used.

The second optical element ES2 may be at least one from among a camera, an infrared camera (IR camera), a dot projector, an infrared illuminator (IR illuminator), and a time-of-flight sensor (ToF sensor).

The housing HM may be coupled to the cover window CW. The cover window CW may be arranged on the front surface of the housing HM. The housing HM may be coupled to the cover window CW to provide a set or predetermined accommodation space. The display panel DP and the optical element ES may be accommodated in the set or predetermined accommodation space provided between the housing HM and the cover window CW.

The housing HM may include a material having relatively high rigidity. For example, the housing HM may include a plurality of frames and/or plates made of glass, plastic, metal, or any suitable combination thereof. The housing HM may reliably protect the components of the display device 1000 accommodated in the internal space from external impact.

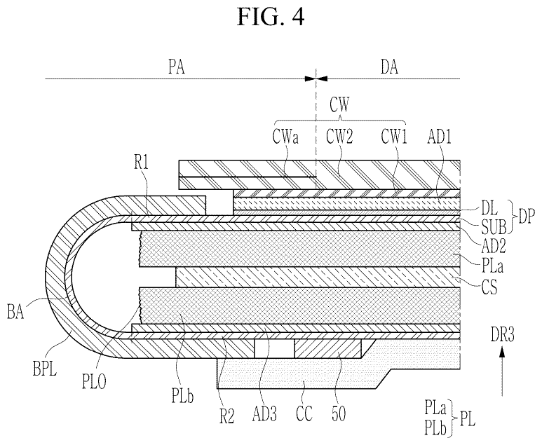

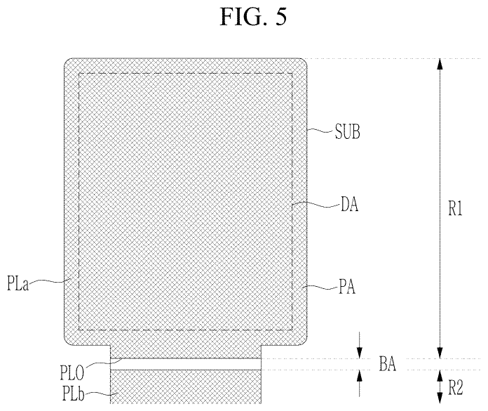

Hereinafter, the display device according to one or more embodiments will be described with reference to FIGS. 4 and 5. FIG. 4 is a cross-sectional view of a portion of the display device according to one or more embodiments. FIG. 5 is a plan view of a protective layer according to one or more embodiments.

FIG. 4 illustrates a cross-section of the non-display area PA of the display panel DP and an area where the flexible printed circuit board (IC) is arranged in the display device according to one or more embodiments.

The cover window CW may be arranged above the display panel DP.

The cover window CW may include a base layer CW1 and a protective layer CW2. In one or more embodiments, the base layer CW1 may be formed of a transparent material. In this case, the base layer CW1 may include glass, a synthetic resin of a transparent material, and/or the like. The base layer CW1 may include at least one layer.

The protective layer CW2 is arranged on the upper surface of the base layer CW1 to prevent, reduce or minimize scratches, and/or the like, from occurring on the base layer CW1. An opaque layer CWa may be arranged on a portion of the protective layer CW2. In one or more embodiments, the opaque layer CWa may be arranged on an edge of the protective layer CW2. The opaque layer CWa may block light. The opaque layer CWa may include a pattern that may be shown to a user if (e.g., when) an image is not displayed.

The cover window CW may be coupled to the display panel DP by the first adhesive layer AD1. The first adhesive layer AD1 may be a transparent adhesive material such as a pressure sensitive adhesive (PSA) and/or an optically clear adhesive (OCA) film.

The display panel DP may include a substrate SUB, a display layer DL arranged on the substrate SUB, and a touch sensing unit arranged on the display layer DL.

The substrate SUB may be a base substrate or a base member. The substrate SUB may be a flexible substrate including a polymer resin such as polyimide, polyamide, and/or polyethylene terephthalate. In one or more embodiments, the substrate SUB may be a rigid substrate made of a material such as glass. The driving element layer may be arranged on the substrate. The driving element layer may include transistors and capacitors that constitute pixel circuit units that output driving currents to light-emitting elements.

According to one or more embodiments, the substrate SUB may include a first area R1 where the display layer DL is arranged, a bending area BA that extends from the first area R1 and is bent, and a second area R2 that extends from the bending area BA and overlaps at least a portion of the first area R1. In this case, the first area R1 may overlap the display region DA, and the bending area BA may overlap the non-display region PA.

The display layer DL may include a driving element layer, a light emitting element layer, and an encapsulation layer that are arranged on the first area R1 of the substrate SUB.

The driving element layer may include gate lines, data lines, power lines, gate control lines, fan-out lines connecting the display driving unit and the data lines, lead lines connecting the display driving unit and the display pads, and/or the like. The driving element layer may include transistors and capacitors constituting the gate driving unit, and gate control lines. The driving element layer may include conductive layers, semiconductor layers, and insulating layers, and may constitute and insulate transistors, capacitors, and signal lines by a combination thereof.

The light-emitting element layer may be arranged on the driving element layer, and may include light-emitting elements and light-emitting areas corresponding to the light-emitting elements. The light-emitting element layer may include a pixel definition layer having an opening defining the light-emitting areas.

The encapsulation layer (or thin film encapsulation layer) may cover the upper surface and side surfaces of the light-emitting element layer, and may prevent or reduce moisture and/or oxygen from penetrating into the light-emitting element layer from the outside. The encapsulation layer may include one or more inorganic layers and one or more organic layers.

The touch sensing unit may be arranged on the encapsulation layer, and may include sensing electrodes. The sensing electrodes may detect the user's touch in a mutual capacitor manner and/or a self-capacitor manner.

A bending protective layer BPL may be arranged in the bending area BA of the substrate SUB to prevent or reduce cracks, and/or the like, from forming in the substrate SUB. The bending protective layer BPL may include a polymer resin such as polyethylene terephthalate (PET), polyimide (PI), and/or the like.

A protective layer PL may be arranged on the rear surface of the substrate SUB. The protective layer PL according to one or more embodiments may include polyimide. The protective layer PL made of a polyimide material may hardly transmit UV light (e.g., have low or no UV light transmittance). The UV light transmittance of the protective layer PL may be less than about 10% or less than about 5%. The protective layer PL according to one or more embodiments may be colored or transparent.

As illustrated in FIG. 5, the protective layer PL may include a first protective layer PLa overlapping the first area R1 in a state in which the substrate SUB is unfolded, and a second protective layer PLb overlapping the second area R2 in a state in which the substrate SUB is unfolded. The protective layer PL may include an opening PLO overlapping the bending area BA of the substrate SUB. The bending of the substrate SUB may be better facilitated by removing the protective layer PL from the bending area BA.

Referring back to FIG. 4, one side surface of the protective layer PL exposed at the opening PLO may include uneven irregularities. The opening PLO of the protective layer PL may be formed through a laser irradiation process. In this case, one side surface of the protective layer PL irradiated with the laser may have traces of the laser irradiation. That is, due to the laser irradiation process, the side surface of the protective layer PL exposed at the opening PLO may include uneven irregularities.

According to one or more embodiments, a second adhesive layer AD2 may be arranged between the protective layer PL and the first area R1. A third adhesive layer AD3 may be arranged between the protective layer PL and the second area R2. The second adhesive layer AD2 and the third adhesive layer AD3 may be formed in substantially the same process. The second adhesive layer AD2 and the third adhesive layer AD3 may include substantially the same material. The second adhesive layer AD2 and the third adhesive layer AD3 may not overlap the bending area BA. The adhesive material may have a form of being removed from the bending area BA.

The second adhesive layer AD2 and the third adhesive layer AD3 may include a UV initiator. The second adhesive layer AD2 and the third adhesive layer AD3 may be formed by changing the adhesion to a stronger state by UV light irradiation after being provided in a weaker adhesive state.

The adhesion in a weaker adhesive state may be about 100 gf/inch or less, and the adhesion in a stronger adhesive state may be about 300 gf/inch to about 1000 gf/inch. The adhesion of the second adhesive layer AD2 and the third adhesive layer AD3 (e.g., after UV light irradiation) may be about 300 gf/inch to about 1000 gf/inch.

According to one or more embodiments, a buffer member CS may be arranged between the protective layers PLs overlapping along the third direction DR3. The buffer member CS may be to absorb external impact to prevent or substantially prevent the display panel DP and/or the like from being damaged. The buffer member CS may include an elastic material such as a sponge formed by foaming rubber, a urethane-based material, and/or an acrylic-based material.

Although FIG. 4 illustrates a buffer member CS as arranged between the protective layers PLs overlapping along the third direction DR3, the present disclosure is not limited thereto, and according to one or more embodiments, the buffer member CS may be replaced with an adhesive layer or an air gap.

The display device according to one or more embodiments may include a protective layer including polyimide. The protective layer including polyimide has excellent or suitable folding characteristics and high-temperature stability, and thus may provide a display device with improved reliability.

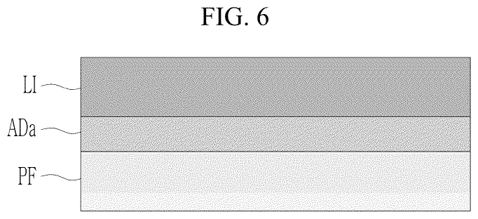

Hereinafter, a manufacturing method of a display device according to one or more embodiments will be described with reference to FIGS. 6 to 13. FIGS. 6 to 13 are diagrams illustrating the manufacturing method of a display device according to one or more embodiments. Descriptions of components substantially identical to the above-described components will not be provided again.

First, referring to FIG. 6, an adhesive material layer ADa is applied on a polyimide film PF. Then, a release paper LI is arranged on the adhesive material layer ADa.

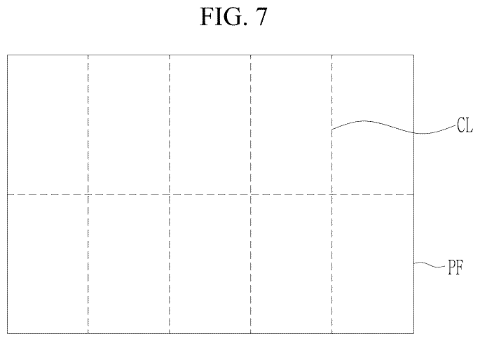

In some embodiments, the polyimide film PF may have a size different from that applied to the final display device. For example, the polyimide film (PF) may proceed (e.g., may be processed) in a large-area film state as illustrated in FIG. 7, and may be cut along a cutting line CL to provide a plurality of polyimide layers (e.g., films), each corresponding to the size of a display device.

Referring back to FIG. 6, the adhesive material layer ADa according to one or more embodiments may include an acrylic compound. In addition, the adhesive material layer ADa may include the UV initiator. As the UV light is irradiated, the UV initiator of the adhesive material layer ADa may react to improve the adhesion of the adhesive material layer ADa.

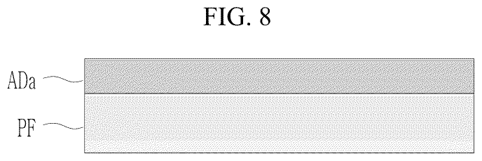

Next, as illustrated in FIG. 8, the release paper LI of FIG. 6 is removed. The exposed adhesive material layer ADa may have a low (e.g., lower) adhesive strength. According to one or more embodiments, the adhesive material layer ADa may have an adhesive strength of about 100 gf/inch or less.

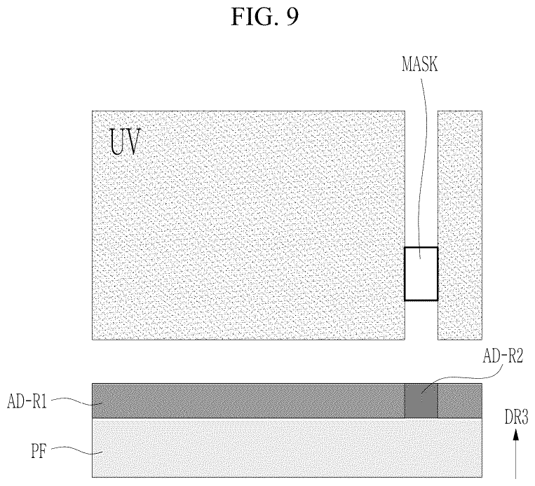

Thereafter, as illustrated in FIG. 9, a mask MASK is arranged on the adhesive material layer ADa. The mask MASK may be arranged at a position overlapping the bending area of the substrate described above.

After the mask MASK is arranged on the adhesive material layer ADa, light in the UV wavelength range is irradiated onto the adhesive material layer ADa. The polyimide film PF according to one or more embodiments may hardly transmit light in the UV wavelength range. The UV light transmittance of the polyimide film PF may be less than about 10%, and may be less than about 5%.

According to the UV light irradiation process, the adhesive material layer ADa may include a first adhesive area AD-R1 having a first adhesion and a second adhesive area AD-R2 having a second adhesion. The second adhesive area AD-R2 may be an area that overlaps the mask MASK and is covered by the mask MASK. The second adhesive area AD-R2 may be an area where the UV light is not irradiated. The first adhesive area AD-R1 may be an area not overlapping with the mask MASK. The first adhesive area AD-R1 may be exposed to the UV light and the adhesion may be improved by the light irradiation. The first adhesion may be greater than the second adhesion. According to one or more embodiments, the first adhesion may be about 300 gf/inch to about 1000 gf/inch, and the second adhesion may be about 100 gf/inch or less.

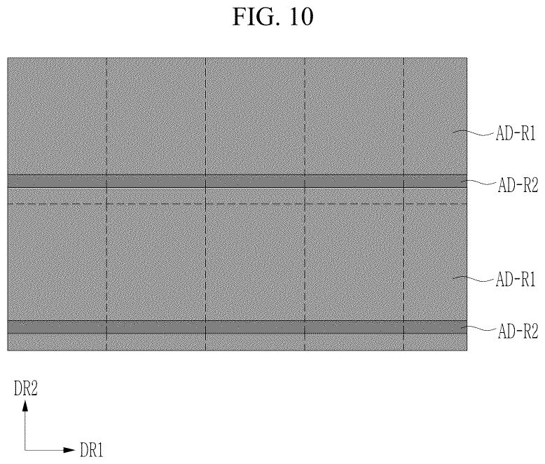

FIG. 10 illustrates that the second adhesive area AD-R2 has a long bar shape extending along one direction, but the present disclosure is not limited thereto, and the shape of the second adhesive area AD-R2 may be suitably modified such as being bent or folded along the second direction DR2.

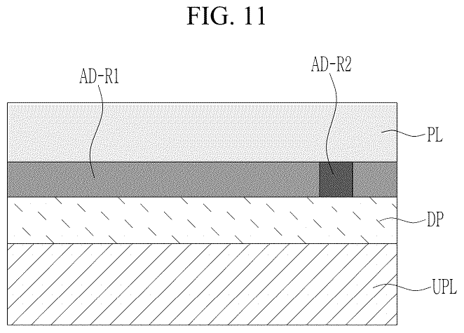

Next, as illustrated in FIG. 11, an adhesive layer AD including the first adhesive area AD-R1 and the second adhesive area AD-R2 is attached to the rear surface of the display panel DP. An upper protective layer UPL for protecting the display panel DP may be arranged on one surface (e.g., upper surface opposite to the rear surface) of the display panel DP.

In this case, the adhesive layer AD and the protective layer PL may be cut to a size suitable for each display device, or may be an adhesive layer and a protective layer in the form of a circle attached to a display panel in the form of a circle. That is, the adhesive layer AD and the protective layer PL may be cut to a size and shape that match the size and shape of each display device, or may be attached to the display panel in the form of a circle.

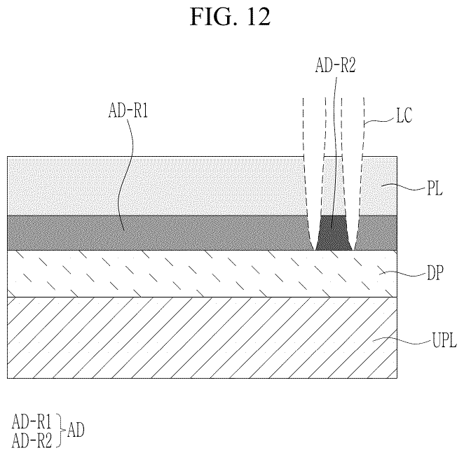

Then, as illustrated in FIG. 12, a laser cutting LC process is performed along the edge of the first adhesive area AD-R1 and/or the edge of the second adhesive area AD-R2. The laser used in the laser cutting process may be a CO₂ laser. The laser may penetrate through the protective layer PL made of the polyimide material and the adhesive layer AD. The laser may not penetrate through the display panel DP.

The side surface of the polyimide protective layer PL exposed by the laser cutting may have traces (e.g., signs) of the laser irradiation. For example, the side surface of the polyimide protective layer PL may be uneven. The side surface of the polyimide protective layer PL may include fine irregularities, for example, that have a concave-convex shape.

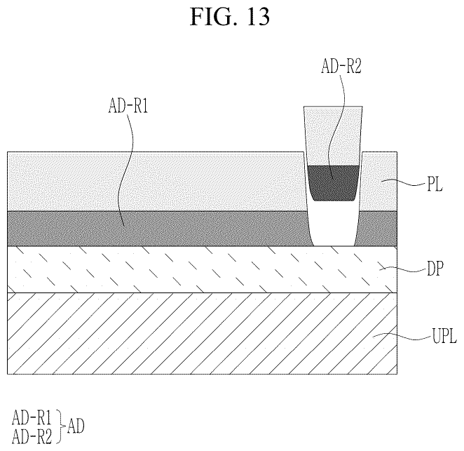

Thereafter, as illustrated in FIG. 13, the second adhesive area AD-R2 and a portion of the polyimide protective layer PL overlapping the second adhesive area AD-R2 may be separated and removed. Because the adhesion of the second adhesive area AD-R2 is relatively lower, it may be easily peeled off from the display panel DP. Due to the removal of the second adhesive area AD-R2, the protective layer PL may include the opening PLO (see FIG. 5). In the opening PLO, the display panel DP, for example, the substrate described above, may be exposed.

According to one or more embodiments, it is possible to use one polyimide film to manufacture a protective layer made of polyimide material for a plurality of display devices. Therefore, it is possible to reduce the time and cost desired or required for the process. In addition, by providing the protective layer including polyimide, it is possible to improve the folding characteristics of the foldable display device, and stability at high temperatures.

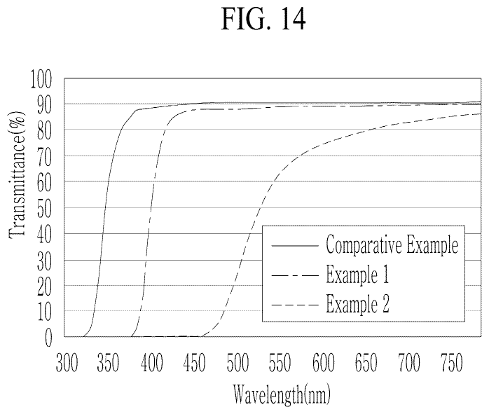

Hereinafter, the UV light transmittance for the Examples and Comparative Example will be described with reference to FIG. 14. FIG. 14 is a graph illustrating UV transmittance for Examples and Comparative Example.

The Comparative Example of FIG. 14 is a PET film, Example 1 is a transparent polyimide film, and Example 2 is a colored polyimide film.

When reviewing the wavelength range of 300 nanometers (nm) to 400 nanometers, which is the UV wavelength range, it may be seen that the polyimide films of Examples 1 and 2 hardly transmit UV light. That is, the polyimide films of Examples 1 and 2 has low or no UV transmittance. Therefore, according to the manufacturing method of a display device according to one or more embodiments, after forming the adhesive material layer on the polyimide film, by irradiating the adhesive material layer with the UV light, it is possible to provide the adhesive layers with different adhesions. That is, the adhesive layers can be patterned to areas of different adhesions by UV irradiation. By attaching the adhesive layer to the display panel and removing the adhesive layer from some areas, it is possible to provide a patterned protective layer.

According to one or more embodiments of the present disclosure, a single polyimide film may be used to create protective layers for multiple display devices, reducing both time and cost. This polyimide protective layer enhances the folding characteristics and high-temperature stability of foldable display devices. UV light transmittance tests, illustrated in FIG. 14, show that polyimide films (both transparent and colored) have low or no UV transmittance compared to PET films. By forming an adhesive layer on the polyimide film and using UV light to create areas with different adhesions, a patterned protective layer may be achieved, which maybe selectively attached to or removed from the display panel.

As used herein, the terms “use,” “using,” and “used” may be considered synonymous with the terms “utilize,” “utilizing,” and “utilized,” respectively. As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The use of “may” when describing embodiments of the inventive concept refers to “one or more embodiments of the inventive concept.”

As used herein, the term “about,” and similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Here, unless otherwise defined, the listing of steps, tasks, or acts in a particular order should not necessarily means that the invention or claims require that particular order. That is, the general rule that unless the steps, tasks, or acts of a method (e.g., a method claim) actually recite an order, the steps, tasks, or acts should not be construed to require one.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The display device, the electronic device, a device for manufacturing the same and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Although embodiments of the present disclosure have been described in more detail hereinabove, the scope of the present disclosure is not limited thereto, but may include several modifications and alterations made by those skilled in the art using a basic concept of the present disclosure as defined in the claims, and equivalents thereof.

### REFERENCE NUMERALS

SUB: Substrate
DL: Display layer
PL: Protective layer
AD: Adhesive layer

What is claimed is:

1. A display device, comprising:
a substrate;
a display layer on a first surface of the substrate;
a protective layer on a second surface of the substrate, the second surface facing away from the first surface; and
an adhesive layer between the display layer and the protective layer,
wherein the substrate comprises:
a first area where the display layer is arranged,
a bending area extending and bent from the first area, and
a second area connected to the bending area and overlapping the first area,
wherein the protective layer comprises an opening overlapping the bending area, and
the protective layer is made of a polyimide material.

2. The display device of claim 1, wherein:
the protective layer is colored or transparent.

3. The display device of claim 1, wherein:
a UV transmittance of the protective layer is less than 10%.

4. The display device of claim 1, wherein:
the display device is folded along a folding axis crossing the display layer.

5. The display device of claim 1, further comprising:
a buffer member on a surface of the protective layer.

6. The display device of claim 1, wherein:
the substrate comprises a display area and a non-display area, and
the bending area and the second area overlap the non-display area.

7. The display device of claim 1, wherein:
the adhesive layer comprises an acrylic compound.

8. The display device of claim 1, wherein:
an adhesion of the adhesive layer is about 300 gf/inch to about 1000 gf/inch.

9. The display device of claim 1, wherein:
the adhesive layer comprises a UV initiator.

10. The display device of claim 1, wherein:
a side surface of the protective layer has a concave-convex shape.

11. A method comprising:
providing an adhesive layer on a polyimide film;
arranging a mask on the adhesive layer and irradiating UV light;
attaching the adhesive layer to a surface of a display panel; and
removing a portion of the polyimide film and a portion of the adhesive layer,
wherein the method is a manufacturing method of a display device.

12. The method of claim 11, wherein:
in the irradiating of the UV light, an adhesion of the adhesive layer is improved.

13. The method of claim 11, wherein:
by irradiating of the UV light, the adhesive layer comprises a first adhesive area having a first adhesion and a second adhesive area having a second adhesion, and
the first adhesion is greater than the second adhesion.

14. The method of claim 13, further comprising:
performing a laser cutting process along an edge of the second adhesive area.

15. The method of claim 14, wherein the removing of the portion of the polyimide film and the portion of the adhesive layer comprises removing the second adhesive area of the adhesive layer and a portion of the polyimide film corresponding to the second adhesive area.

16. The method of claim 11, wherein:
a UV light transmittance of the polyimide film is less than about 10%.

17. The method of claim 11, wherein:
the polyimide film is colored or transparent.

18. The method of claim 11, wherein:
the display device is folded along a folding axis crossing the display panel.

19. The method of claim 11, wherein:
the adhesive layer comprises a UV initiator.

20. The method of claim 11, wherein:
the adhesive layer comprises an acrylic compound.

21. An electronic device comprising a display device, the display device comprising:
a substrate;
a display layer on a first surface of the substrate;
a protective layer on a second surface of the substrate, the second surface facing away from the first surface; and
an adhesive layer between the display layer and the protective layer,
wherein the substrate comprises:
a first area where the display layer is arranged,
a bending area extending and bent from the first area, and
a second area connected to the bending area and overlapping the first area,
wherein the protective layer comprises an opening overlapping the bending area, and
the protective layer is made of a polyimide material.

22. The electronic device of claim 20, wherein the electronic device is selected from among a television, a laptop, a monitor, a billboard, the Internet of Things (IoT), portable electronic devices, a mobile phone, a smart phone, a tablet personal computer (PC), a mobile communication terminal, an electronic notebook, an electronic book, a portable multimedia player (PMP), a navigation, an ultra mobile PC (UMPC), wearable devices, a smart watch, a watch phone, a glasses-type (kind) display, a head mounted display (HMD), a center information display (CID) on a car's instrument panel and/or a car's center fascia and/or dashboard, a room mirror display that replaces a car's side mirror, and a display on a rear surface of a front seat as entertainment for a car's rear seat.
